(19) United States
(12) Patent Application Publication
(10) Pub. No.: US 2010/0244921 A1
(43) Pub. Date: Sep. 30, 2010

(54) PROGRAMMABLE DELAY LINE CIRCUIT WITH GLITCH AVOIDANCE

(75) Inventor: Jean Barbier, Montpellier (FR)

Correspondence Address: SCHWABE, WILLIAMSON & WYATT, P.C., 1420 FIFTH, SUITE 3400, SEATTLE, WA, 98101-4010, US

(73) Assignee: M2000 SA., Bievre (FR)

(21) Appl. No.: 12/415,507

(22) Filed: Mar. 31, 2009

(51) Int. Cl. H03H 11/26; H03K 17/693

(52) U.S. Cl. 327/277; 327/276

(57) ABSTRACT

Embodiments of programmable delay line circuits are disclosed herein. The delay line circuit may comprise a first multiplexer having a first input coupled with an input line; a second multiplexer having a first input, and a second input coupled with an output of the first multiplexer, and an output coupled with a second input of the first multiplexer; a third multiplexer having a first input coupled with the output of the second multiplexer, a second input coupled with the input line, and an output coupled with an output line; a first control gate coupled with the third multiplexer to control the third multiplexer; and a second control gate coupled with the second multiplexer to control the second multiplexer; wherein the first and second control gates selectively control the second and third multiplexer, responsive to a delay value encoded in Gray Code.

### TECHNICAL FIELD

The present invention relates to the fields of integrated circuit (IC), and more specifically, the present invention relates to programmable delay line circuits with glitch avoidance, and their usage in reconfigurable circuits.

### BACKGROUND

A programmable delay line (hereafter called a delay line) is a circuit where an input signal may be passed to the output of the delay line after a programmably determined delay. Delay line circuits are typically used to adjust the relative delay difference between two signals to achieve reliable data transfer. However, there may be several disadvantages of the known delay line circuits. One of the potential disadvantages is that most of the known delay line circuits suffer from glitches. Another potential disadvantage is that the known delay line circuits may have a low adjustability regarding the number of delays and the step of each delay in accordance with various applications.

### BRIEF DESCRIPTION OF THE DRAWINGS

Embodiments of the present invention will be described by way of exemplary embodiments, but not limitations, illustrated in the accompanying drawings in which like references denote similar elements, and in which:

FIG. 1 illustrates a delay line circuit according to various embodiments;

FIG. 2 illustrates operation process of the delay line circuit in FIG. 1 according to various embodiments;

FIG. 3 illustrates another delay line circuit according to various embodiments; and

FIG. 4 illustrates a reconfigurable circuit according to various embodiments.

### DETAILED DESCRIPTION OF ILLUSTRATIVE EMBODIMENTS

Illustrative embodiments of the present invention include, but are not limited to delay line circuits constructed with multiplexers.

Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific numbers, materials, and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Further, various operations will be described as multiple discrete operations, in turn, in a manner that is most helpful in understanding the illustrative embodiments; however, the order of description should not be construed as to imply that these operations are necessarily order dependent. In particular, these operations need not be performed in the order of presentation.

The phrase “in one embodiment” is used repeatedly. The phrase generally does not refer to the same embodiment; however, it may. The terms “comprising,” “having,” and “including” are synonymous, unless the context dictates otherwise.

Gray Code is a binary numeral system where two successive values differ in only one bit. Table 1 provides an example of decimal numbers 0 to 15 and their corresponding binary Gray Code values. In various embodiments, a delay value of a delay line circuit may represent the discrete number of delays to be added into an input signal. In various embodiments, the delay value may be encoded in Gray Code.

TABLE 1
Decimal numbers and corresponding Gray Code values

| 0 | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|
| 0000 | 0001 | 0011 | 0010 | 0110 | 0111 | 0101 | 0100 | 1100 | 1101 | 1111 | 1110 | 1010 | 1011 | 1001 | 1000 |

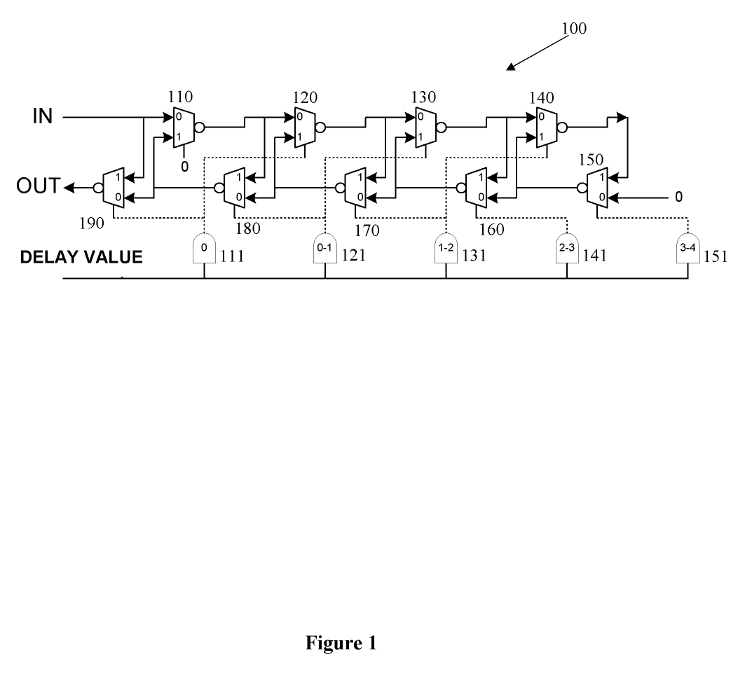

FIG. 1 illustrates a delay line circuit 100 that may handle a delay value ranging from decimal number 0 to 4, in accordance with various embodiments. As illustrated, for the embodiments, the delay line circuit 100 may comprise nine multiplexers 110 to 190 as illustrated in FIG. 1. In various embodiments, each of the multiplexers 110 to 190 may have four terminals, an input terminal “0”, an input terminal “1”, an output terminal and a control terminal. In various embodiments, each multiplexer may be configured to pass the value at the input terminal “0” to the output terminal when the control terminal of the multiplexer is coupled to logic “0”, and each of the multiplexers may be configured to pass the value at the input terminal “1” to the output terminal when the control terminal of the multiplexer is coupled to logic “1”. In various embodiments, the output terminal of each multiplexer may be coupled to the input terminal “0” of the next multiplexer, except that the output terminal of multiplexer 140 may be coupled to the input terminal “1” of multiplexer 150, the input terminal “0” of multiplexer 150 may be coupled to any value, e.g. a constant value, and the output of multiplexer 190 may be used as the output signal of the delay line circuit 100. In various embodiments, the input terminals “0” of multiplexers 110, 120, 130 and 140 may be coupled to the input terminals “1” of multiplexers 190, 180, 170 and 160, respectively. In various embodiments, the input terminals “1” of multiplexers 110, 120, 130 and 140 may be coupled to the input terminals “0” of multiplexers 190, 180, 170 and 160, respectively. And, in accordance with various embodiments, the input terminal “0” of multiplexer 150 may be coupled to an external signal which may be logic “0”.

For the embodiments, the delay line circuit 100 may further comprise five control gates 111 to 151 and the five control gates may be configured to receive the delay value encoded in Gray Code. In accordance with various embodiments, the control gates may be five different AND gates that are configured to output logic 0 or 1 respectively based on the delay value. In various embodiments, the output of control gate 111 may be coupled to the control terminals of multiplexers 120 and 190; the output of control gate 121 may be coupled to the control terminals of multiplexers 130 and 180; the output of control gate 131 may be coupled to the control terminals of multiplexers 140 and 170; the output of control gate 141 may be coupled to the control terminal of multiplexer 160; the output of control gate 151 may be coupled to the control terminal of multiplexer 150. In various embodiments, when the delay value represents decimal number 0, only control gates 111 and 121 may be configured to output logic 1; when the delay value represents decimal number 1, only control gates 121 and 131 may be configured to output logic 1; when the delay value represents decimal number 2, only control gates 131 and 141 may be configured to output logic 1; when the delay value represents decimal number 3, only control gates 141 and 151 may be configured to output logic 1; when the delay value represents decimal number 4, only control gate 151 may be configured to output logic 1. In various embodiments, the control terminal of multiplexer 110 may be coupled with an external signal which may be logic 0.

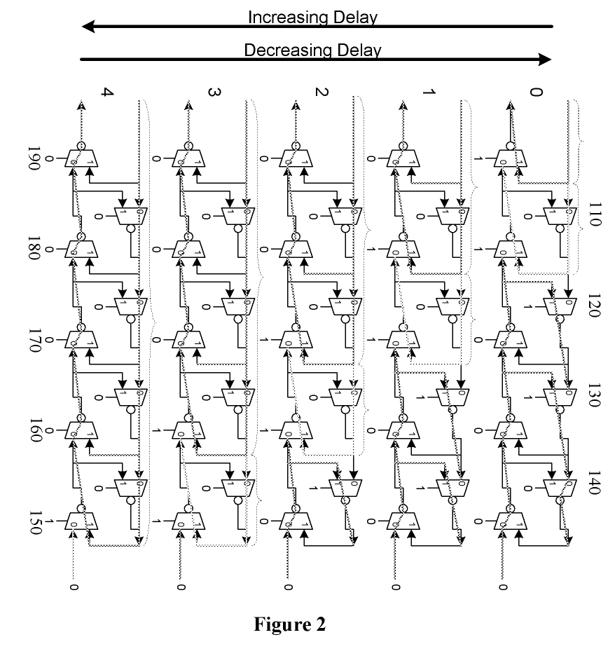

FIG. 2 illustrates the detailed operation process of the delay line circuit 100 in accordance with various embodiments. In various embodiments, the first to fifth rows may represent five different operational modes of the delay line circuit 100 when the delay value varies from decimal number 0 to 4. The bold lines represent the signal connectivity implemented by the multiplexers as determined by the values on the control terminals of the multiplexers for each operational mode. When the delay value represents decimal number 0, the control terminal of multiplexers 120, 130, 180 and 190 may be coupled to logic “1” and the control terminals of the other multiplexers may be coupled to logic “0”. In various embodiments, an input signal may be received at the input terminal “0” of multiplexer 110 and may be passed through multiplexer 110 to the input terminal “0” of multiplexer 120 when the control terminal of multiplexer 110 is coupled to logic 0. But the input signal may not be passed further from the input terminal “0” of multiplexer 120 to multiplexer 130 because as stated above the control terminal of multiplexer 120 may be coupled to logic “1” when the delay value represents decimal number 0. Instead, the input signal may be turned around and coupled to the input terminal “1” of multiplexer 180. As stated above, when the delay value represents decimal number 0, the control terminal of multiplexer 180 may be coupled to logic “1”. So, the input signal may be further passed through multiplexer 180 to the input terminal “0” of multiplexer 190. However, when the delay value represents decimal number 0, the control terminal of multiplexer 190 may be coupled to logic “1”, thus the input signal may not be further passed from the input terminal “0” to the output terminal of multiplexer 190. On the other hand, as illustrated in FIG. 2, the input signal may also be coupled to the input terminal “1” of multiplexer 190 and may be outputted as the output of the delay line circuit 100. In various embodiments, when the delay value represents decimal number 0, the input signal may be passed to the output of the delay line circuit through a single multiplexer 190.

In various embodiments, when the delay value represents decimal number 1, the control terminal of multiplexers 130, 140, 170 and 180 may be coupled to logic “1” and the control terminals of the other multiplexers may be coupled to logic “0”. In various embodiments, the input signal may be passed through multiplexers 110 and 120 to the input terminal “0” of multiplexer 130, but may not be further passed through multiplexer 130 because the control terminal of multiplexer 130 is coupled to logic “1”. Instead, the input signal may be turned around and coupled to the input terminal “1” of multiplexer 170. As stated above, when the delay value represents decimal number 1, the control terminal of multiplexer 170 may be coupled to logic “1”. So, the input signal may be passed through multiplexer 170 to the input terminal “0” of multiplexer 180. However, as stated above, when the delay value represents decimal number 1, the control terminal of multiplexer 180 may be coupled to “1”, thus the value at the input terminal “0” of multiplexer 180 cannot be passed through. Rather, in various embodiments, the output from multiplexer 110 may be coupled to the input terminal “1” of multiplexer 180. So, the input signal may be passed through multiplexers 110 and 180 to the input terminal “0” of multiplexer 190. And because when the delay value represents decimal number 1, the control terminal of multiplexer 190 may be coupled to be logic “0”, the input signal may be passed through the multiplexer 190 as the output of the delay line circuit 100. In various embodiments, the input signal may be passed to the output of the delay line circuit 100 through multiplexers 110, 180 and 190 when the delay value represents decimal number 1.

In various embodiments, as illustrated in FIG. 2, when the delay value represents decimal number 2, the input signal may be passed to the output of the delay line circuit 100 through multiplexers 110, 120, 170, 180 and 190; when the delay value represents decimal number 3, the input signal may be passed to the output of the delay line circuit 100 through multiplexers 110, 120, 130, 160, 170, 180 and 190; when the delay value represents decimal number 4, the input signal may be passed to the output of the delay line circuit 100 through all the multiplexers in delay line circuit 100. Thus, when the delay value represents decimal number 0, there is one multiplexer on the path between the input and output of the delay line. Correspondingly, when the delay value represents decimal number 1, 2, 3 and 4, there are 3, 5, 7 and 9 multiplexors, respectively, on the path between the input and output of the delay line. Each multiplexer has some delay between its input and output, in various embodiments, the delay of each multiplexer is programmable and all multiplexers can be designed identically to have substantially the same delay. Also, in various embodiments, the number of multiplexers in the delay line circuit may be programmable. Thus, the delay line can be programmed to provide different delays between the input and output in increments of two multiplexor delays.

As illustrated in FIG. 2, the first bracket in each row indicates the active delay path that the input signal travels through. And the second bracket in each row indicates the path that may not be active but may also carry the input signal and be ready to be included in the active path if the delay value is increased by 1. Therefore, glitches may be avoided when the delay value is increased or decreased by 1 because the output of only one of the control gates changes value due to the nature of the Gray encoding of the delay value. When the delay value is decreased, the effective path through the delay line is decreased and no glitch can occur. A very short 0 or 1 pulse may be lost, but such a pulse is below the bandwidth of this circuit and would be filtered anyway. When the delay value is increased, the effective path through the delay line is increased. The circuit design of the multiplexer ensures that any glitch that might occur is sufficiently short to be effectively filtered by the circuit. Also, in particular to delay increase, the glitches may be avoided because the input signal may be already contained in the path indicated by the second bracket, to be included to generate the increase of delay in FIG. 2.

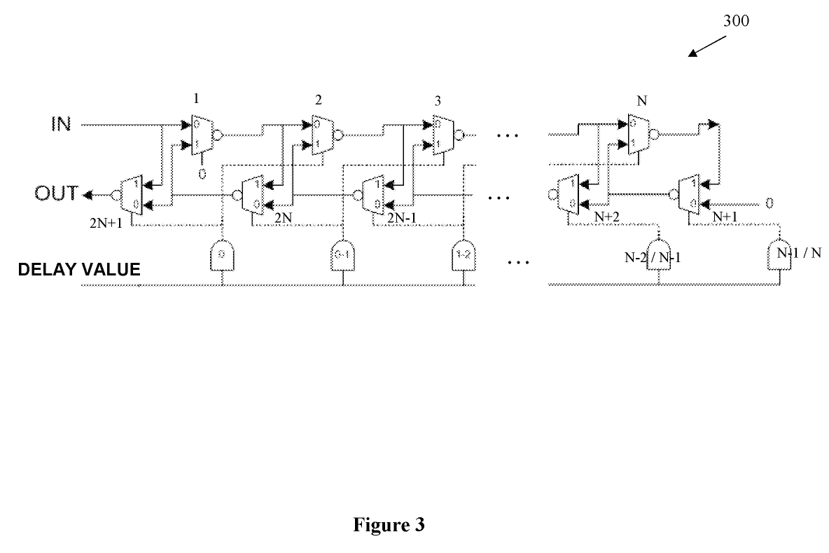

FIG. 3 illustrates a delay line circuit 300 which may handle a delay value ranges from 0 to N, and N is an integer. In accordance with various embodiments. In various embodiments, the maximum delay value may be N, and the delay line circuit 300 may be formed by 2N+1 multiplexers. In various embodiments, the output terminal of each multiplexer may be coupled to the input terminal “0” of the next multiplexer, except that the output terminal of multiplexer N may be coupled to the input terminal “1” of multiplexer N+1 and the output of multiplexer 2N+1 may be used as the output of the delay line circuit. In various embodiments, the input terminal “0” of multiplexer X may be coupled to the input terminal “1” of multiplexer Y, and the input terminal “1” of multiplexer X may be coupled to the input terminal “0” of multiplexer Y, and X is an integer ranges from 1 to N and Y is an integer may be described as Y=2N+2−X. In various embodiments, the input terminal “0” of multiplexer N+1 may be coupled to external signal such as logic “0”.

In various embodiments, the delay line circuit may also comprise N+1 control gates. In various embodiments, control gate A may be configured to control multiplexers B and C, and A is an integer ranges from 1 to N−1, B is an integer that may be described as B=A+1, and C is an integer that may be described as C=2N+2−A. In various embodiments, control gate N may be configured to control multiplexer N+2, and control gate N+1 may be configured to control multiplexer N+1. In various embodiments, the control terminal of the first multiplexer may be coupled to a constant value such as logic 0. In various embodiments, control gate D may be configured to output logic 1 only when the delay value equals to D−2 or D−1, wherein D is an integer ranges from 2 to N+1. In various embodiments, the first control gate may output logic 1 only when the delay value is logic 0. Also, in various embodiments, the control gates may be AND gates and due to the characteristic of Gray Code that two successive values differ in only one bit, AND gates with M−1 inputs may suffice to be used in the delay line circuit 300 if the delay value is an M-bit Gray Code value, where M is an integer.

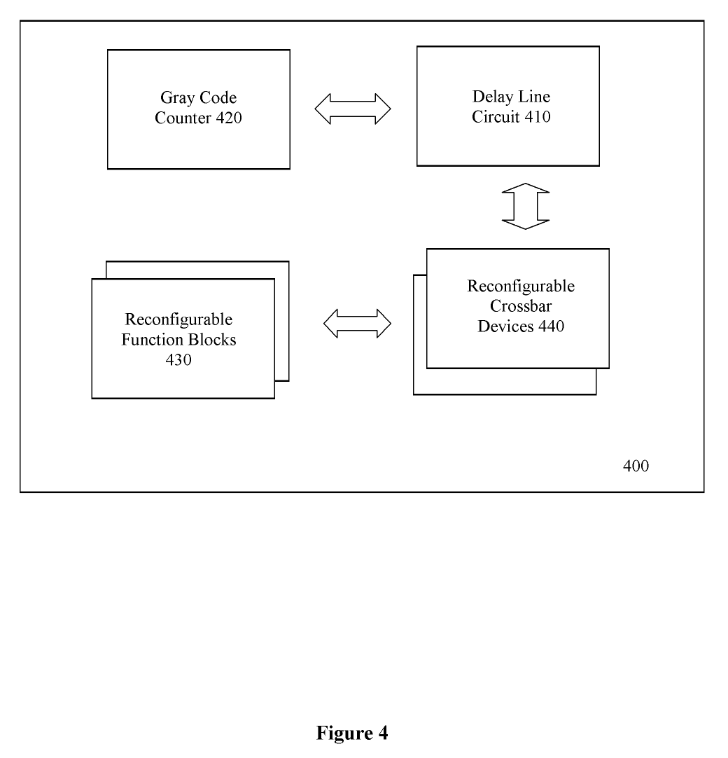

FIG. 4 illustrates a reconfigurable circuit 400 comprising a delay line circuit 410 in accordance with various embodiments. In various embodiments, the reconfigurable circuit 400 may further comprise a Gray Code counter 420 which may be coupled with the delay line circuit 410 and configured to generate the delay value encoded in Gray Code for the delay line circuit 410. In various embodiments, the reconfigurable circuit 400 may further comprise a plurality of reconfigurable function blocks 430 and a plurality of reconfigurable crossbar devices 440, which may be coupled with the delay line circuit 410. In alternate embodiments, Gray Code counter 420 and/or the delay line circuit 410 may be disposed in one of reconfigurable function block 430 or one of reconfigurable crossbar devices 440.

Although specific embodiments have been illustrated and described herein, it will be appreciated by those of ordinary skill in the art that a wide variety of alternate and/or equivalent implementations may be substituted for the specific embodiments shown and described, without departing from the scope of the embodiments of the present invention. This application is intended to cover any adaptations or variations of the embodiments discussed herein. Therefore, it is manifestly intended that the embodiments of the present invention be limited only by the claims and the equivalents thereof.

What is claimed is:

1. A programmable delay line circuit comprising:
a first multiplexer having a first input coupled with an input line;
a second multiplexer having a first input, and a second input coupled with an output of the first multiplexer, and an output coupled with a second input of the first multiplexer;
a third multiplexer having a first input coupled with the output of the second multiplexer, a second input coupled with the input line, and an output coupled with an output line;
a first control gate coupled with the third multiplexer to control the third multiplexer; and
a second control gate coupled with the second multiplexer to control the second multiplexer;
wherein the first and second control gates selectively control the third and second multiplexer, responsive to a delay value encoded in Gray Code, to provide programmable delay to a signal provided to the input line, and the first multiplexer is controlled by a constant value.

2. The programmable delay line circuit of claim 1, wherein the first control gate and the second control gates are responsive when the delay value represents decimal number 0, and only the second control gate is responsive when the delay value represents decimal number 1.

3. The programmable delay line circuit of claim 1, further comprising:
a fourth multiplexer having a first input coupled with the output of the first multiplexer, a second input coupled with the output of the second multiplexer, and an output coupled with the second input of the second multiplexer;
a fifth multiplexer having a first input coupled with the output of the second multiplexer, a second input coupled with the output of the first multiplexer, and an output coupled with the second input of the first multiplexer and the first input of the third multiplexer;
the first control gate further coupled with the fourth multiplexer to control the fourth multiplexer; and
a third control gate coupled with the fifth multiplexer to control the fifth multiplexer;
wherein the first control gate controls the third and the fourth multiplexer, the second control gate controls the second multiplexer, and the third control gate controls the fifth multiplexer, responsive to a delay value, to provide programmable delay to the signal provided to the input line.

4. The programmable delay line circuit of claim 3 wherein only the first and third control gates are responsive when the delay value represents decimal number 0, only the third and second control gates are responsive when the delay value represents decimal number 1, and only the second control gate is responsive when the delay value represents decimal number 2.

5. A programmable delay line circuit comprising:
a first delay element having a first input coupled with an input line;
a second delay element having a first input, and a second input coupled with an output of the first delay element, and an output coupled with a second input of the first delay element;
an output multiplexer having a first input coupled with the output of the second delay element, a second input coupled with the input line, and an output coupled with an output line;
a first control gate coupled with the output multiplexer to control the output multiplexer; and
a second control gate coupled with the second delay element to control the second delay element;
wherein the first and second control gates selectively control the second delay element and the output multiplexer, responsive to a delay value encoded in Gray Code, to provide programmable delay to a signal provided to the input line, and the first delay element is controlled by a constant value.

6. The programmable delay line circuit of claim 5 further comprising
a first additional delay element having a first input coupled with the output of the first delay element, a second input coupled with the output of the second delay element, and an output coupled with the second input of the second delay element;
a second additional delay element having a first input coupled with the output of the second delay element, a second input coupled with the output of the first delay element, and an output coupled with the second input of the first delay element and the first input of the output multiplexer;
the first control gate further coupled with the first additional delay element to control the first additional delay element; and
a third control gate coupled with the second additional delay element to control the second additional delay element;
wherein the first control gate controls the output multiplexer and the first additional delay element, the second control gate controls the second delay element, and the third control gate controls the second additional delay element, responsive to the delay value, to provide programmable delay to the signal provided to the input line.

7. The programmable delay line circuit of claim 6, wherein only the first and third control gates are responsive when the delay value represents decimal number 0, only the third and second control gates are responsive when the delay value represents decimal number 1, and only the second control gate is responsive when the delay value represents decimal number 2.

8. A reconfigurable circuit comprising:
a plurality of reconfigurable function blocks;
a plurality of reconfigurable crossbar devices coupled with the plurality of reconfigurable function blocks;
a programmable delay circuit included with at least a selected one of the reconfigurable function blocks or reconfigurable crossbar devices, the programmable delay circuit comprising:
a first multiplexer having a first input coupled with an input line;
a second multiplexer having a first input, and a second input coupled with an output of the first multiplexer, and an output coupled with a second input of the first multiplexer;
a third multiplexer having a first input coupled with the output of the second multiplexer, a second input coupled with the input line, and an output coupled with an output line;
a first control gate coupled with the third multiplexer to control the third multiplexer; and
a second control gate coupled with the second multiplexer to control the second multiplexer;
wherein the first and second control gates selectively control the third and second multiplexer, responsive to a delay value encoded in Gray Code, to provide programmable delay to a signal provided to the input line, and the first multiplexer is controlled by a constant value.

9. The reconfigurable circuit of claim 8, wherein the first control gate and the second control gates are responsive when the delay value represents decimal number 0, and only the second control gate is responsive when the delay value represents decimal number 1.

10. The reconfigurable circuit of claim 8, where in the programmable delay line circuit further comprising:
a fourth multiplexer having a first input coupled with the output of the first multiplexer, a second input coupled with the output of the second multiplexer, and an output coupled with the second input of the second multiplexer;
a fifth multiplexer having a first input coupled with the output of the second multiplexer, a second input coupled with the output of the first multiplexer, and an output coupled with the second input of the first multiplexer and the first input of the third multiplexer;
the first control gate further coupled with the fourth multiplexer to control the fourth multiplexer; and
a third control gate coupled with the fifth multiplexer to control the fifth multiplexer;
wherein the first control gate controls the third and the fourth multiplexer, the second control gate controls the second multiplexer, and the third control gate controls the fifth multiplexer, responsive to a delay value, to provide programmable delay to the signal provided to the input line.

11. The reconfigurable circuit of claim 10, wherein only the first and third control gates are responsive when the delay value represents decimal number 0, only the third and second control gates are responsive when the delay value represents decimal number 1, and only the second control gate is responsive when the delay value represents decimal number 2.

12. The reconfigurable circuit of claim 8, further comprising a Gray Code counter coupled with the programmable delay line circuit, configured to generate the delay value encoded in Gray Code.
